(19) United States
(12) Patent Application Publication
(10) Pub. No.: US 2024/0222109 A1
(43) Pub. Date: Jul. 4, 2024

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventor: Naofumi OHASHI, Toyama-shi (JP)

(73) Assignee: Kokusai Electric Corporation, Tokyo (JP)

(21) Appl. No.: 18/591,336

(22) Filed: Feb. 29, 2024

(30) Foreign Application Priority Data
Jan. 3, 2023 (JP) 2023-031373

(51) Int. Cl. H01L 21/02; C23C 16/34; C23C 16/455; C23C 16/458; C23C 16/46; C23C 16/52; H01L 23/00

(52) U.S. Cl. CPC H01L 21/02271; C23C 16/345; C23C 16/45544; C23C 16/4586; C23C 16/46; C23C 16/52; H01L 21/0217; H01L 23/562

(57) ABSTRACT

A processing chamber that processes a substrate; a first gas supply mechanism that supplies a first film-forming gas to a front surface of the substrate; a second gas supply mechanism that supplies a second film-forming gas to a back surface of the substrate; a substrate heating table that heats the substrate in the processing chamber; a lifting/lowering mechanism that lifts and lowers the substrate between a first position where the substrate can be transferred into and out of the processing chamber and a second position which is closer to the substrate heating table than the first position and where the substrate is not in contact with the substrate heating table; and a controller capable of controlling the first and second gas supply mechanisms, the substrate heating table, and the lifting/lowering mechanism so as to form films on both surfaces of the substrate while heating the substrate at the second position.

### CROSS-REFERENCE TO RELATED APPLICATION

This application is based upon and claims the benefit of priority from Japanese Patent Application No. 2023-031373, filed on Mar. 1, 2023, the entire contents of which are incorporated herein by reference.

### FIELD

The present disclosure relates to a substrate processing apparatus, a method of manufacturing a semiconductor device, and a recording medium.

### DESCRIPTION OF THE RELATED ART

As one step of a semiconductor device manufacturing process, a process of supplying a film-forming gas to a front surface of a substrate placed on a substrate placing table to form a film on the substrate may be performed.

### SUMMARY

When a film is formed by supplying a film-forming gas only to a front surface of a substrate, the substrate may be warped due to a stress of the film.

The present disclosure provides a technique capable of suppressing warpage of a substrate.

An embodiment of the present disclosure provides a technique including:
a processing chamber that processes a substrate;
a first gas supply mechanism that supplies a first film-forming gas to a front surface of the substrate;
a second gas supply mechanism that supplies a second film-forming gas to a back surface of the substrate;
a substrate heating table that heats the substrate in the processing chamber;
a lifting/lowering mechanism that lifts and lowers the substrate at least between a first position where the substrate can be transferred into and out of the processing chamber and a second position which is closer to the substrate heating table than the first position and where the substrate is not in contact with the substrate heating table; and
a controller configured to be capable of controlling the first gas supply mechanism, the second gas supply mechanism, the substrate heating table, and the lifting/lowering mechanism so as to form films on both surfaces of the substrate while heating the substrate at the second position.

### BRIEF DESCRIPTION OF THE DRAWINGS

FIG. 1 is a longitudinal sectional view for describing a configuration of a substrate processing apparatus according to an embodiment of the present disclosure, and is a diagram illustrating a position of a substrate during substrate transfer.

FIG. 2 is a longitudinal sectional view for describing the configuration of the substrate processing apparatus according to the embodiment of the present disclosure, and is a diagram illustrating a position of the substrate during substrate processing.

FIG. 3 is a block diagram for describing a configuration of a controller of the substrate processing apparatus according to the embodiment of the present disclosure.

FIG. 4 is an example of a flowchart for describing a substrate processing step according to the embodiment of the present disclosure.

FIG. 5 is a diagram for describing a position of a substrate during substrate processing according to another embodiment of the present disclosure.

### DETAILED DESCRIPTION

### Embodiment of the Present Disclosure

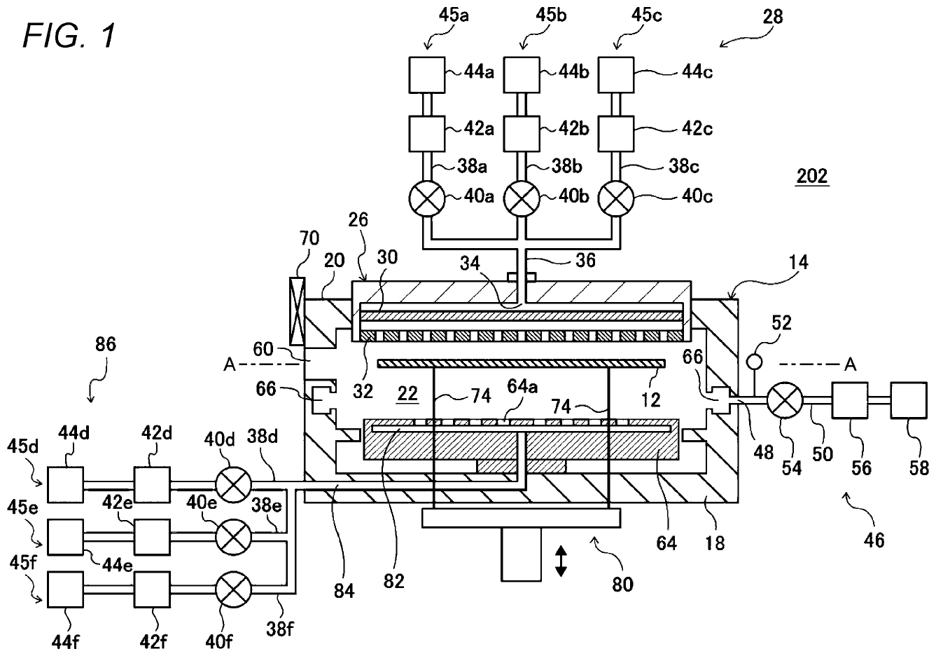

An embodiment of the present disclosure will be described below mainly with reference to FIGS. 1 to 4. Furthermore, the drawings used in the following description are all schematic, and a dimensional relationship among elements, a ratio among the elements, and the like illustrated in the drawings do not necessarily coincide with actual ones. In addition, a dimensional relationship among elements, a ratio among the elements, and the like do not necessarily coincide among the plurality of drawings.

### (1) Configuration of Substrate Processing Apparatus

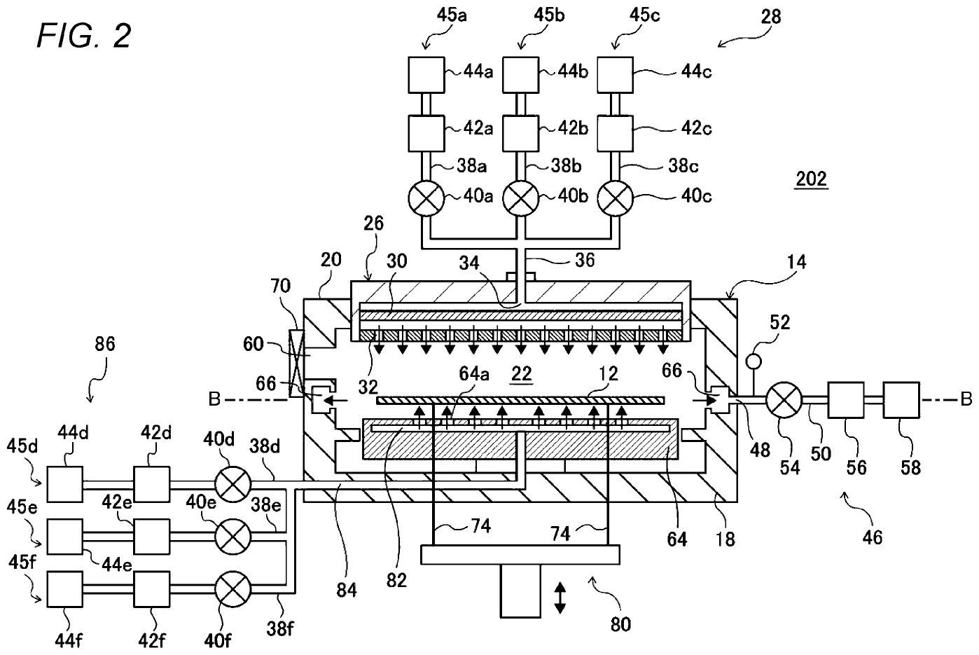

FIG. 1 is a diagram illustrating a state in which a substrate 12 is at a substrate transfer position A serving as a first position during substrate transfer (also referred to as substrate loading/unloading) during which the substrate 12 can be transferred in a processing container 202 of a substrate processing apparatus. FIG. 2 is a diagram illustrating a state in which the substrate 12 is at a substrate processing position B serving as a second position during substrate processing (also referred to as film-forming processing) during which the substrate 12 is processed in the processing container 202 of the substrate processing apparatus.

### (Processing Container)

The processing container 202 includes a container 14 that constitutes a processing chamber 22 in which the substrate 12 is processed. The container 14 communicates with a substrate transfer chamber through a gate valve 70.

The container 14 includes a container body 18 whose upper portion is opened, and a lid 20 that closes the upper opening of the container body 18. The container 14 forms the processing chamber 22 having a sealed structure therein.

### (Gas Introducer)

The lid 20 is provided with a gas introducer 26. The gas introducer 26 is disposed so as to face the substrate 12 in the processing chamber 22. The gas introducer 26 includes a gas dispersion plate 30 that is disposed on a gas introduction upstream side and has a plurality of gas holes, and a shower plate 32 that is disposed on a gas introduction downstream side of the gas dispersion plate 30, has a large number of gas holes, and disperses a gas in a shower shape. A gas supply pipe 36 is connected to the gas introducer 26.

### (Susceptor)

A susceptor 64 serving as a substrate heating table that heats the substrate 12 is fixed in the container body 18. The susceptor 64 includes a heater serving as a heating mechanism. That is, the substrate 12 is configured to be heated by radiant heat from the susceptor 64. The susceptor 64 is provided with a gas supply space 82. A plurality of gas supply holes 64a communicating with the gas supply space 82 is formed in an upper surface of the susceptor 64. A gas supply pipe 84 is connected to the gas supply space 82.

### (Gas Supply System)

A gas supply system 28 includes a gas supply pipe 36, and is configured to supply a gas into the processing chamber 22 through the gas supply pipe 36 and a gas introduction port 34 formed substantially at a center of an upper surface of the gas introducer 26. The gas supply system 28 includes the gas supply pipe 36 communicating with the gas introduction port 34, gas supply pipes 38a, 38b, and 38c branched from the gas supply pipe 36 on a gas supply upstream side of the gas supply pipe 36, and valves 40a, 40b, and 40c serving as opening/closing valves that open and close gas flow paths and mass flow controllers (MFCs) 42a, 42b, and 42c serving as gas flow rate controllers, which are provided in the gas supply pipes 38a, 38b, and 38c, respectively.

The gas supply pipe 38a is provided with a gas supply source 44a, the MFC 42a, and the valve 40a in this order from a gas supply upstream direction. The gas supply pipe 38b is provided with a gas supply source 44b, the MFC 42b, and the valve 40b in this order from the gas supply upstream direction. The gas supply pipe 38c is provided with a gas supply source 44c, the MFC 42c, and the valve 40c in this order from the gas supply upstream direction.

That is, the gas supply system 28 is configured to supply a desired type of gas into the processing chamber 22 at a desired gas flow rate and a desired gas ratio from a position located at an upper portion in the container 14 and above the substrate 12 through the gas introducer 26. In addition, the gas supply system 28 is configured to supply a gas to a front surface of the substrate 12 in the processing chamber 22 through the gas introducer 26.

A gas supply system 86 includes a gas supply pipe 84, and is configured to supply a gas into the processing chamber 22 through the gas supply pipe 84. The gas supply system 86 includes the gas supply pipe 84, gas supply pipes 38d, 38e, and 38f branched from the gas supply pipe 84 on a gas supply upstream side of the gas supply pipe 84, and valves 40d, 40e, and 40f and MFCs 42d, 42e, and 42f which are provided in the gas supply pipes 38d, 38e, and 38f, respectively.

The gas supply pipe 38d is provided with a gas supply source 44d, the MFC 42d, and the valve 40d in this order from a gas supply upstream direction. The gas supply pipe 38e is provided with a gas supply source 44e, the MFC 42e, and the valve 40e in this order from the gas supply upstream direction. The gas supply pipe 38f is provided with a gas supply source 44f, the MFC 42f, and the valve 40f in this order from the gas supply upstream direction.

That is, the gas supply system 86 is configured to supply a desired type of gas into the processing chamber 22 at a desired gas flow rate and a desired gas ratio from a position located at a lower portion in the container 14 and below the substrate 12. In addition, the gas supply system 86 is configured to supply a gas to a back surface of the substrate 12 in the processing chamber 22 through the gas supply space 82 and the gas supply holes 64a.

That is, the gas supply system 28 that supplies a gas to the front surface of the substrate 12 and the gas supply system 86 that supplies a gas to the back surface of the substrate 12 are each configured to supply a desired gas into the processing chamber 22 at a desired gas flow rate and a desired gas ratio. Therefore, it is configured such that a supply condition of a film-forming gas supplied from the gas supply system 28 to the front surface of the substrate 12 (also referred to as a first film-forming gas) and a supply condition of a film-forming gas supplied from the gas supply system 86 to the back surface of the substrate 12 (also referred to as a second film-forming gas) can be each set. That is, it is possible to supply a gas whose flow rate is regulated to each of the front surface and the back surface of the substrate 12. This makes it possible to form films having different compositions, films having different thicknesses, and the like on the front surface and the back surface of the substrate 12 without being limited to films having the same composition or the same thickness.

The gas introducer 26 and the gas supply system 28 are used as a first gas supply mechanism that supplies a gas to the front surface of the substrate in the processing chamber 22. The gas supply space 82, the gas supply holes 64a (the susceptor 64 in the present embodiment), and the gas supply system 86 are used as a second gas supply mechanism that supplies a gas to the back surface of the substrate in the processing chamber 22.

A source gas that is a processing gas and a film-forming gas is supplied from the gas supply pipe 38a into the processing chamber 22 through the MFC 42a, the valve 40a, the gas supply pipe 36, the gas introduction port 34, and the gas introducer 26. A reactant gas that is a processing gas and a film-forming gas and reacts with the source gas is supplied from the gas supply pipe 38b into the processing chamber 22 through the MFC 42b, the valve 40b, the gas supply pipe 36, the gas introduction port 34, and the gas introducer 26. An inert gas is supplied from the gas supply pipe 38c into the processing chamber 22 through the MFC 42c, the valve 40c, the gas supply pipe 36, the gas introduction port 34, and the gas introducer 26.

A source gas that is a processing gas and a film-forming gas is supplied from the gas supply pipe 38d into the processing chamber 22 through the MFC 42d, the valve 40d, the gas supply pipe 84, the gas supply space 82, and the gas supply holes 64a. A reactant gas that is a processing gas and a film-forming gas and reacts with the source gas is supplied from the gas supply pipe 38e into the processing chamber 22 through the MFC 42e, the valve 40e, the gas supply pipe 84, the gas supply space 82, and the gas supply holes 64a. An inert gas is supplied from the gas supply pipe 38f into the processing chamber 22 through the MFC 42f, the valve 40f, the gas supply pipe 84, the gas supply space 82, and the gas supply holes 64a.

A source gas supply system 45a includes the gas supply pipe 38a, the MFC 42a, the valve 40a, the gas supply pipe 36, the gas introduction port 34, and the gas introducer 26. The gas supply source 44a may be included in the source gas supply system 45a. A reactant gas supply system 45b includes the gas supply pipe 38b, the MFC 42b, the valve 40b, the gas supply pipe 36, the gas introduction port 34, and the gas introducer 26. The gas supply source 44b may be included in the reactant gas supply system 45b. An inert gas supply system 45c includes the gas supply pipe 38c, the MFC 42c, the valve 40c, the gas supply pipe 36, the gas introduction port 34, and the gas introducer 26. The gas supply source 44c may be included in the inert gas supply system 45c. The inert gas supply system 45c may be referred to as a purge gas supply system. The source gas supply system 45a and the reactant gas supply system 45b may be collectively considered as a film-forming gas supply system.

A source gas supply system 45d includes the gas supply pipe 38d, the MFC 42d, the valve 40d, the gas supply pipe 84, the gas supply space 82, and the gas supply holes 64a. The gas supply source 44d may be included in the source gas supply system 45d. A reactant gas supply system 45e includes the gas supply pipe 38e, the MFC 42e, the valve 40e, the gas supply pipe 84, the gas supply space 82, and the gas supply holes 64a. The gas supply source 44e may be included in the reactant gas supply system 45e. An inert gas supply system 45f includes the gas supply pipe 38f, the MFC 42f, the valve 40f, the gas supply pipe 84, the gas supply space 82, and the gas supply holes 64a. The gas supply source 44f may be included in the inert gas supply system 45f. The inert gas supply system 45f may be referred to as a purge gas supply system. The source gas supply system 45d and the reactant gas supply system 45e may be collectively considered as a film-forming gas supply system.

### (Periphery of Susceptor)

An annular passage 66 communicating with the processing chamber 22 is formed on a side wall of the container body 18. The annular passage 66 is formed in an annular shape substantially horizontally on the side wall of the container body 18. The annular passage 66 is formed at a substrate processing position B (FIG. 2, hereinafter, this position is referred to as a substrate processing position B) of the container body 18. The annular passage 66 is formed so as to communicate with an exhaust hole 48. The exhaust hole 48 is formed so as to communicate with the processing chamber 22 through the annular passage 66. It is configured such that an atmosphere inside the processing chamber 22 is exhausted to the outside of the processing chamber 22 through the annular passage 66 and the exhaust hole 48.

A transfer port 60 through which the substrate 12 is transferred into and out of the processing chamber 22 is formed above the annular passage 66 on the side wall of the container body 18. The transfer port 60 is formed at a substrate transfer position A (FIG. 1, hereinafter, this position is referred to as a substrate conveyance position A) of the container body 18. The transfer port 60 is provided with the gate valve 70 serving as an opening/closing valve that isolates an atmosphere inside the substrate transfer chamber from that inside the processing chamber 22 in an openable and closable manner. The unprocessed substrate 12 is loaded from the substrate transfer chamber into the processing chamber 22 through the transfer port 60, and the processed substrate 12 is unloaded from the processing chamber 22 to the substrate transfer chamber through the transfer port 60.

### (Lifting/Lowering Mechanism)

A lifting/lowering mechanism 80 includes a support pin 74 serving as a substrate supporter that supports the substrate 12 in the processing chamber 22 from below. A plurality of support pins 74 is erected. Each of the plurality of support pins 74 is held by the lifting/lowering mechanism 80 and is configured to be able to vertically move (also referred to as movable). That is, the substrate 12 is configured to be able to be lifted and lowered in the processing chamber 22 on the plurality of support pins 74 by lifting and lowering by the lifting/lowering mechanism 80. The lifting/lowering mechanism 80 is configured to be able to adjust the position of the substrate 12 in the processing chamber 22 in the vertical direction in multiple stages in each of steps such as a substrate loading/unloading step and a film-forming step described later. Specifically, the lifting/lowering mechanism 80 is configured to lift and lower the substrate 12 at least between the substrate transfer position A where the substrate 12 can be transferred into and out of the processing chamber 22 and the substrate processing position B which is closer to the susceptor 64 than the substrate transfer position A and where the substrate 12 is not in contact with the susceptor 64. The support pins 74 are configured to pass through the susceptor 64. The support pins 74 are configured to be able to protrude and retract from a front surface of the susceptor 64 according to lifting and lowering of the lifting/lowering mechanism 80, and are configured to be able to lift and lower the substrate 12 to and from the substrate transfer position A or the substrate processing position B.

That is, when the lifting/lowering mechanism 80 lifts the support pins 74 and the substrate 12 is at the substrate transfer position A where substrate transfer can be performed, the substrate 12 can be supported on the plurality of support pins 74 in a state where the plurality of support pins 74 protrudes from the susceptor 64. Then, it is configured such that the substrate 12 can be loaded and unloaded between the processing chamber 22 and the substrate transfer chamber through the transfer port 60. When the lifting/lowering mechanism 80 lowers the support pins 74 and the substrate 12 is at the substrate processing position B which is below the substrate transfer position A and where substrate processing can be performed, it is configured such that substrate processing can be performed on the substrate 12 on the plurality of support pins 74 in a state where the plurality of support pins 74 protrudes from the susceptor 64.

### (Exhaust System)

The container body 18 is provided with an exhaust system 46 that exhausts an atmosphere inside the processing chamber 22 through the exhaust hole 48. An exhaust piping 50 is connected to the exhaust hole 48. The exhaust piping 50 is provided with a pressure sensor 52, a valve 54, an APC valve 56 that is a pressure regulator that regulates a pressure inside the processing chamber 22, and a vacuum pump 58 in this order from a gas flow upstream direction. The exhaust system 46 includes the exhaust piping 50, the pressure sensor 52, the valve 54, and the APC valve 56. The vacuum pump 58 may be included in the exhaust system 46. The pressure sensor 52 monitors a pressure inside the processing chamber 22. The MFCs 42a to 42f, the valves 40a to 40f and 54, the APC valve 56, and the like are controlled on the basis of a pressure value acquired by the pressure sensor 52 to regulate a gas supply amount and a gas exhaust amount, and the pressure inside the processing chamber 22 is thereby controlled to a desired value.

### (Controller)

A controller 121 serving as a control means controls the units described above so as to perform a substrate processing step described later.

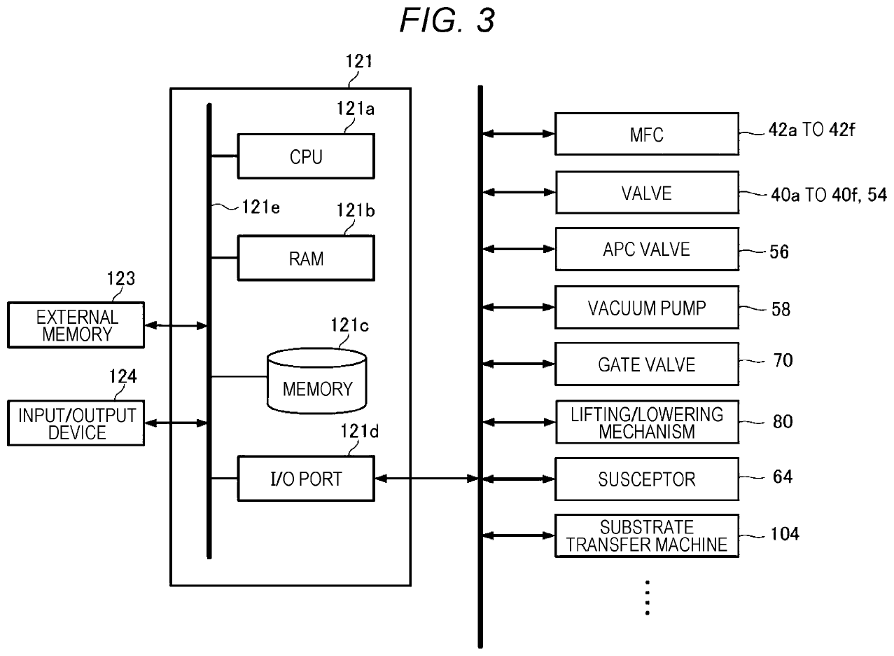

As illustrated in FIG. 3, the controller 121 is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 124 configured as, for example, a touch panel or the like is connected to the controller 121.

The memory 121c includes, for example, a flash memory, a hard disk drive (HDD), or the like. In the memory 121c, a control program that controls an operation of the substrate processing apparatus, a process recipe in which procedures, conditions, and the like of substrate processing described later are described, and the like are readably stored. Furthermore, the process recipe is combined so as to cause the controller 121 to perform each procedure in the substrate processing step described later to obtain a predetermined result, and functions as a program. Hereinafter, the process recipe, the control program, and the like are also collectively and simply referred to as a program. Furthermore, in the present specification, the term “program” may include only a process recipe alone, only a control program alone, or both of these. The RAM 121b is configured as a memory area (work area) in which a program, data, and the like read by the CPU 121a are temporarily stored.

The I/O port 121d is connected to the MFCs 42a to 42f, the valves 40a to 40f and 54, the APC valve 56, the vacuum pump 58, the gate valve 70, the lifting/lowering mechanism 80, the susceptor 64, a substrate transfer machine 104, and the like described above.

The CPU 121a is configured to read the control program from the memory 121c and perform the control program, and to read the process recipe from the memory 121c in response to an input or the like of an operation command from the input/output device 124. Then, the CPU 121a is configured to control, in accordance with the content of the read process recipe, a heating operation of the substrate 12 by the susceptor 64, a pressure regulating operation by the APC valve 56, flow rate regulating operations of gases by the MFCs 42a to 42f and the valves 40a to 40f and 54, a lifting and lowering operation of the substrate 12 by the lifting/lowering mechanism 80, a transfer operation of the substrate 12 by the substrate transfer machine 104, and the like.

Furthermore, the controller 121 is not limited to a configuration as a dedicated computer, and may be configured as a general-purpose computer. The controller 121 according to the present embodiment can be configured by, for example, preparing an external memory (for example, a magnetic tape, a magnetic disk such as a flexible disk or a hard disk, an optical disk such as a CD or a DVD, a magneto-optical disk such as an MO, or a semiconductor memory such as a USB memory (USB flash drive) or a memory card) 123 storing the above-described program, and, for example, installing the program into a general-purpose computer using the external memory 123. However, the means for supplying the program to the computer is not limited to the case of supplying the program via the external memory 123. For example, the program may be supplied using a communication means such as the Internet or a dedicated line without via the external memory 123. Furthermore, the memory 121c and the external memory 123 are configured as computer-readable recording media. Hereinafter, the memory 121c and the external memory 123 are also collectively and simply referred to as a recording medium. Furthermore, in the present specification, the term “recording medium” may include only the memory 121c alone, only the external memory 123 alone, or both of these.

### (2) Substrate Processing Step

Next, a step in which a thin film is formed on the substrate 12 by using the processing container 202 of the substrate processing apparatus having the above-described configuration will be described as one step of a semiconductor manufacturing process. Furthermore, in the following description, operations of units constituting the substrate processing apparatus are controlled by the controller 121.

The term “substrate” used in the present specification may mean a substrate itself, or a laminate of a substrate and a predetermined layer or film formed on a surface of the substrate. The phrase “surface of a substrate” used in the present specification may mean a surface of a substrate itself or a surface of a predetermined layer or the like formed on the substrate. In the present specification, the phrase “forming a predetermined layer on a substrate” may mean directly forming a predetermined layer on a surface of a substrate itself, or forming a predetermined layer on a layer or the like formed on the substrate. In the present specification, the term “substrate” is synonymous with the term “wafer”.

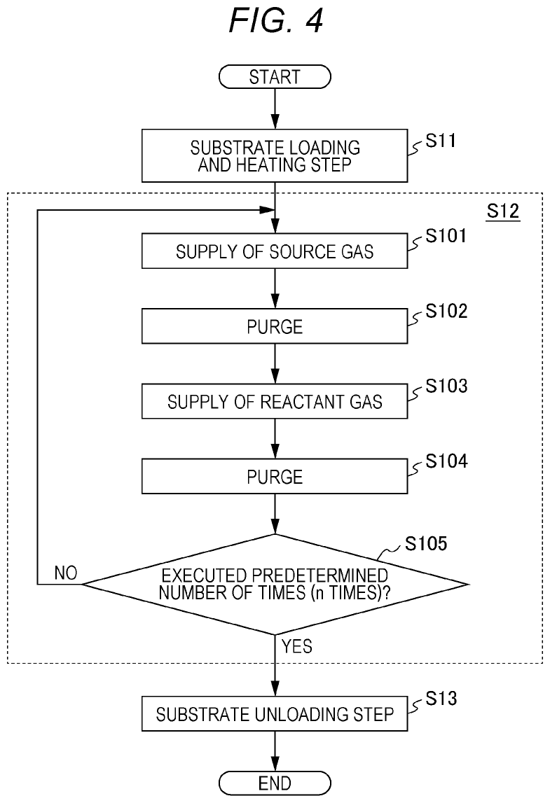

FIG. 4 is a flowchart illustrating an outline of the substrate processing step according to the embodiment of the present disclosure.

### (Substrate Loading and Heating Step: S11)

First, the controller 121 lifts the support pins 74 to the substrate transfer position A illustrated in FIG. 1 by the lifting/lowering mechanism 80, and causes the support pins 74 to pass through the through-holes of the susceptor 64. As a result, the support pins 74 protrude from a surface of the susceptor 64 by a predetermined height at the substrate transfer position A. Subsequently, the controller 121 opens the gate valve 70 to cause the processing chamber 22 to communicate with the substrate transfer chamber. Then, the controller 121 loads the substrate 12 from the substrate transfer chamber into the processing chamber 22 using the substrate transfer machine 104, and transfers the substrate 12 onto the support pins 74. As a result, the substrate 12 is supported in a horizontal posture on the support pins 74 protruding from the surface of the susceptor 64.

After the controller 121 loads the substrate 12 into the processing chamber 22, the controller 121 retracts the substrate transfer machine 104 to the outside of the processing chamber 22, and closes the gate valve 70 to seal the processing chamber 22. Thereafter, the controller 121 lowers the substrate 12 to the substrate processing position B illustrated in FIG. 2 by the lifting/lowering mechanism 80 and stops the substrate 12. At this time, the substrate 12 is not in contact with the susceptor 64. At this time, a distance between the susceptor 64 and the substrate 12 is shorter (also referred to as narrow) than a distance between the susceptor 64 and the substrate 12 at the time of substrate loading/unloading. Specifically, a distance between an upper surface of the susceptor 64 and a lower surface of the substrate 12 is, for example, 100 μm to 3 mm. When the distance between the upper surface of the susceptor 64 and the lower surface of the substrate 12 is less than 100 μm, it may be difficult to uniformly form a film on the back surface of the substrate 12. When the distance is 100 μm or more, a film can be uniformly formed on the back surface of the substrate 12. When the distance between the upper surface of the susceptor 64 and the lower surface of the substrate 12 exceeds 3 mm, a radiation heating effect by the susceptor 64 is not sufficient in some cases. When the distance is 3 mm or less, the radiation heating effect can be improved.

Furthermore, in the present specification, expression of a numerical range such as “100 μm to 3 mm” means that a lower limit value and an upper limit value are included in the range. Therefore, for example, “100 μm to 3 mm” means “100 μm or more and 3 mm or less”. The same applies to other numerical ranges.

When the controller 121 stops the substrate 12 at the substrate processing position B, the controller 121 opens the valve 54 to cause the processing chamber 22 and the APC valve 56 to communicate with each other and to cause the APC valve 56 and the vacuum pump 58 to communicate with each other. By regulating a conductance of the exhaust piping 50 with the APC valve 56, the controller 121 controls an exhaust flow rate of the processing chamber 22 by the vacuum pump 58, and maintains a pressure inside the processing chamber 22 at a predetermined pressure.

In this manner, in the substrate loading and heating step (S11), the pressure inside the processing chamber 22 is controlled to be a predetermined pressure, and the susceptor 64 is controlled such that a surface temperature of the substrate 12 is, for example, 700 to 1000° C., which is a processing temperature.

Furthermore, the processing temperature in the present specification means a temperature of the substrate 12 or a temperature inside the processing chamber 22, and a processing pressure means a pressure inside the processing chamber 22. A processing time means a time during which the processing is continued. The same applies to the following description.

### (Film-Forming Step: S12)

Next, as ae film-forming step (S12), the following steps S101 to S105 are performed. In the film-forming step (S12), a case where a step of alternately supplying different processing gases as a film-forming gas is performed one or more times will be described as an example.

In the film-forming step, in a state where the controller 121 supports the substrate 12 on the support pins 74 at the substrate processing position B illustrated in FIG. 2, the controller 121 heats the substrate 12 and supplies a gas into the processing chamber 22 from each of the front surface side and the back surface side of the substrate 12. Therefore, the film-forming step may be referred to as the substrate processing step. The controller 121 controls the gas supply system 28, the gas supply system 86, the susceptor 64, the lifting/lowering mechanism 80, and the like so as to form films on both surfaces of the substrate 12 while heating the substrate 12 at the substrate processing position B.

An interval between the substrate 12 on the support pins 74 and the gas introducer 26 in the film-forming step is wider than an interval between the substrate 12 on the support pins 74 and the gas introducer 26 in the substrate loading/unloading step (S11 and S13). This makes it possible to suppress an increase in the temperature of the gas introducer 26 due to radiation heat from the susceptor 64.

### (Supply of Source Gas: Step S101)

First, a source gas is supplied to each of both surfaces of the substrate 12 in the processing chamber 22 and exhausted from the processing chamber 22. Specifically, the controller 121 opens the valve 40a to cause the source gas as the first film-forming gas to flow into the gas supply pipe 38a. A flow rate of the source gas is regulated by the MFC 42a. The source gas is supplied into the processing chamber 22 through the gas supply pipe 36, the gas introduction port 34, and the gas introducer 26, and is exhausted from the exhaust piping 50 through the annular passage 66 and the exhaust hole 48. At this time, the controller 121 may open the valve 40c to supply an inert gas from the gas supply pipe 38c. Simultaneously, the controller 121 opens the valve 40d to cause the source gas as the second film-forming gas to flow into the gas supply pipe 38d. A flow rate of the source gas is regulated by the MFC 42d. The source gas is supplied into the processing chamber 22 through the gas supply pipe 84, the gas supply space 82, and the gas supply holes 64a, and is exhausted from the exhaust piping 50 through the annular passage 66 and the exhaust hole 48. At this time, the controller 121 may open the valve 40f to supply an inert gas from the gas supply pipe 38f. Here, “simultaneous” includes “partially simultaneous”. At this time, the valve 54 is opened, and the APC valve 56 controls a pressure inside the processing chamber 22 to be a predetermined processing pressure.

In this step, the source gas is supplied to both surfaces, that is, the front surface and the back surface (also referred to as the upper surface and the lower surface) of the substrate 12. As a result, a first layer is formed on the front surface of the substrate 12 and a second layer is formed on the back surface of the substrate 12. At this time, the first layer and the second layer are films having the same composition, and the first layer which is a film deposited on the front surface of the substrate 12 by the source gas supplied from the gas supply system 28 and the second layer which is a film deposited on the back surface of the substrate 12 by the source gas supplied from the gas supply system 86 are films having the same composition and having the same thickness. In this manner, warpage of the substrate 12 is suppressed.

As the source gas, for example, a source gas containing silicon (Si) can be used. As the source gas containing Si, for example, a chlorosilane-based gas such as a dichlorosilane (SiH₂Cl₂, abbreviation: DCS) gas, a trichlorosilane (SiHCl₃, abbreviation: TCS) gas, a tetrachlorosilane (SiCl₄, abbreviation: STC) gas, or a hexachlorodisilane (Si₂Cl₆, abbreviation: HCDS) gas, a fluorosilane-based gas such as a tetrafluorosilane (SiF₄) gas, an inorganic silane-based gas such as a disilane (Si₂H₆, abbreviation: DS) gas, or an amino silane-based gas such as a trisdimethylaminosilane (Si [N(CH₃)_{2]3}H, abbreviation: 3DMAS) gas can be used. One or more of these gases can be used as the source gas.

As the inert gas, for example, a nitrogen (N₂) gas or a rare gas such as an argon (Ar) gas, a helium (He) gas, a neon (Ne) gas, or a xenon (Xe) gas can be used. One or more of these gases can be used as the inert gas.

### (Purge: Step S102)

After supply of the source gas is stopped, the processing chamber 22 is purged. Specifically, the controller 121 closes the valves 40a and 40d to stop supply of the source gas. At this time, the controller 121 vacuum-exhausts the inside of the processing chamber 22 using the vacuum pump 58 with the APC valve 56 kept open, and removes the source gas remaining inside the processing chamber 22 and having not reacted or having contributed to formation of the first layer and the second layer and by-products from the inside of the processing chamber 22. At this time, the controller 121 maintains supply of the inert gas into the processing chamber 22 with the valves 40c and 40f kept open. The inert gas acts as a purge gas.

### (Supply of Reactant Gas: Step S103)

Subsequently, a reactant gas is supplied to each of both surfaces of the substrate 12 in the processing chamber 22 and exhausted from the processing chamber 22. Specifically, the controller 121 opens the valve 40b to cause the reactant gas as the first film-forming gas to flow into the gas supply pipe 38b. A flow rate of the reactant gas is regulated by the MFC 42b. The reactant gas is supplied into the processing chamber 22 through the gas supply pipe 36, the gas introduction port 34, and the gas introducer 26, and is exhausted from the exhaust piping 50 through the annular passage 66 and the exhaust hole 48. At this time, the controller 121 may open the valve 40c to supply an inert gas from the gas supply pipe 38c. Simultaneously, the controller 121 opens the valve 40e to cause the reactant gas as the second film-forming gas to flow into the gas supply pipe 38e. A flow rate of the reactant gas is regulated by the MFC 42e. The reactant gas is supplied into the processing chamber 22 through the gas supply pipe 84, the gas supply space 82, and the gas supply holes 64a, and is exhausted from the exhaust piping 50 through the annular passage 66 and the exhaust hole 48. At this time, the controller 121 may open the valve 40f to supply an inert gas from the gas supply pipe 38f. At this time, the valve 54 is opened, and the APC valve 56 controls a pressure inside the processing chamber 22 to be a predetermined processing pressure.

In this step, the reactant gas is supplied to each of both surfaces, that is, the front surface and the back surface of the substrate 12. As a result, the first layer on the front surface of the substrate 12 is modified to a third layer, and the second layer on the back surface of the substrate 12 is modified to a fourth layer. At this time, the third layer and the fourth layer are films having the same composition, and the third layer which is a film deposited on the front surface of the substrate 12 by the reactant gas supplied from the gas supply system 28 and the fourth layer which is a film deposited on the back surface of the substrate 12 by the reactant gas supplied from the gas supply system 86 are films having the same composition and having the same thickness. In this manner, warpage of the substrate 12 is suppressed.

As the reactant gas, for example, an N-containing gas containing nitrogen (N) can be used. As the N-containing gas, for example, a hydrogen nitride-based gas such as an ammonia (NH₃) gas, a diazene (N₂H₂) gas, a hydrazine (N₂H₄) gas, or an N₃H₈ gas can be used. One or more of these gases can be used as the reactant gas.

### (Purge: Step S104)

After supply of the reactant gas is stopped, the processing chamber 22 is purged. Specifically, the controller 121 closes the valves 40b and 40e to stop supply of the reactant gas. At this time, the controller 121 vacuum-exhausts the inside of the processing chamber 22 using the vacuum pump 58 with the APC valve 56 kept open, and removes the reactant gas remaining inside the processing chamber 22 and having not reacted or having contributed to formation of the first layer and the second layer and by-products from the inside of the processing chamber 22. At this time, the controller 121 maintains supply of the inert gas into the processing chamber 22 with the valves 40c and 40f kept open. The inert gas acts as a purge gas.

### (Predetermined Number of Times Execution: Step S105)

Steps S101 to S104 described above are defined as one cycle, and the cycle is performed a predetermined number of times (n times, n is an integer of 1 or more) to form a predetermined film having a predetermined thickness on each of the front surface and the back surface of the substrate 12. As the predetermined film, for example, a silicon nitride film (SiN film) can be formed, and for example, a SiN film can be formed on each of the front surface and the back surface of the substrate 12. That is, the film formed on the front surface of the substrate 12 and the film formed on the back surface of the substrate 12 can be films having the same composition. That is, the film deposited on the front surface of the substrate 12 by the source gas and the reactant gas supplied from the gas supply system 28 and the film deposited on the back surface of the substrate 12 by the source gas and the reactant gas supplied from the gas supply system 86 can be films having the same composition. In addition, the film deposited on the front surface of the substrate 12 by the source gas and the reactant gas supplied from the gas supply system 28 and the film deposited on the back surface of the substrate 12 by the source gas and the reactant gas supplied from the gas supply system 86 can be films having the same thickness. By forming the films on both surfaces of the substrate 12 in this manner, warpage of the substrate 12 can be suppressed.

### (Substrate Unloading Step: S13)

After a predetermined film having a predetermined thickness is formed on each of both surfaces of the substrate 12, the processed substrate 12 is lifted to the substrate transfer position A by the lifting/lowering mechanism 80 in a reverse procedure to the above-described substrate loading and heating step (S11), and the processed substrate 12 is thereby unloaded from the processing chamber 22 to the substrate transfer chamber.

Here, in a single wafer type apparatus that forms a film one by one on a substrate, a film-forming gas is supplied to a front surface of the substrate to form a film on the substrate. However, when a film is formed only on the front surface of the substrate, the substrate may be warped due to a stress of the film. In addition, a multilayer pattern may be formed on the front surface of the substrate as a semiconductor device is miniaturized, and in this case, warpage of the substrate is significant. In order to suppress the warpage of the substrate, it is effective to form films on both surfaces of the substrate.

However, in a case where a film is formed by placing a substrate on a susceptor, a film can be formed only on one surface of the substrate, and in order to form films on both surfaces of the substrate, a film is formed on one surface, and then the substrate is inverted and a film is formed on the other surface. Since a film is formed on one surface at a time in this manner, it takes time to form films on both surfaces of the substrate, and a throughput is deteriorated. In addition, when a film is formed on the other surface, particles may adhere to the surface on which a film is previously formed, or the surface on which a film is previously formed may be damaged.

According to the present disclosure, it is possible to simultaneously form films on both surfaces of a substrate. Therefore, it is possible to improve a throughput while suppressing warpage of the substrate. In addition, characteristics of a film can be improved. That is, one or more effects described above can be obtained.

### Other Embodiment of the Present Disclosure

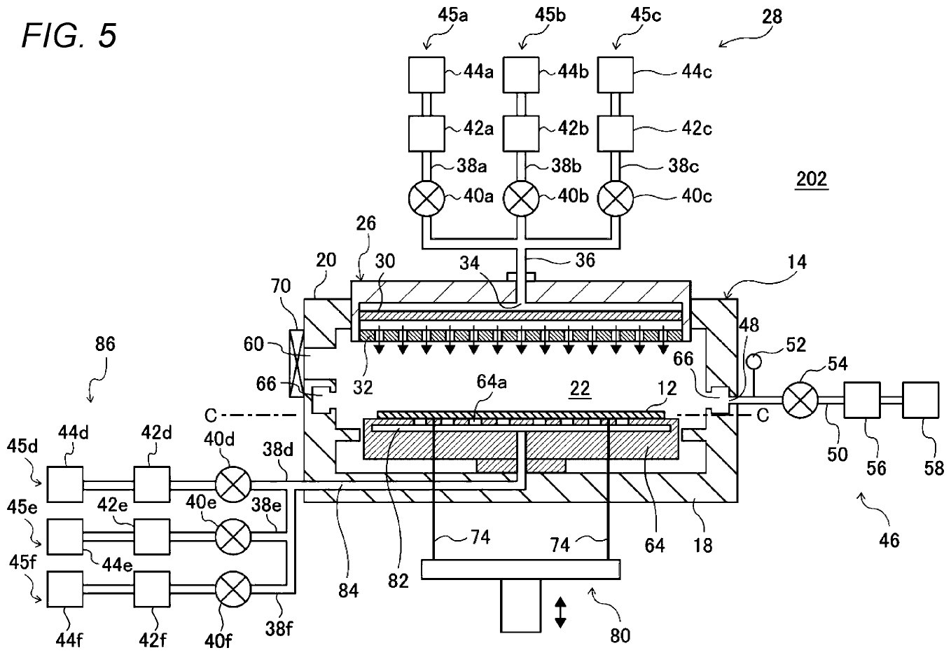

Next, a substrate processing step according to another embodiment of the present disclosure will be described with reference to FIG. 5. Furthermore, in a substrate processing apparatus in the present embodiment, elements that are substantially the same as those described in FIG. 1 are denoted by the same reference numerals, and description thereof will be omitted.

In the present embodiment, in the film-forming step (S12) described above, there is a timing at which the substrate 12 is placed on the susceptor 64 at a substrate placing position C (FIG. 5, hereinafter, this position is referred to as a substrate placing position C) serving as a third position from the substrate processing position B by lifting and lowering the support pins 74 by the lifting/lowering mechanism 80. That is, the controller 121 stops supply of a gas from the gas supply system 86 and stops supply of a gas from the back surface of the substrate 12 every predetermined number of times execution (S105) described above and every predetermined period during film formation. In this state, the controller 121 performs control to lower the substrate 12 from the substrate processing position B to the substrate placing position C by the lifting/lowering mechanism 80, after a lapse of a predetermined time, to lift the substrate 12 from the substrate placing position C to the substrate processing position B, and to perform the film-forming processing (S101 to S104). That is, during the film-forming step, the substrate 12 is moved between the substrate processing position B and the substrate placing position C.

Also in the present embodiment, similar effects to those in the embodiment described above can be obtained. In addition, in the present embodiment, it is further possible to suppress adhesion and consolidation of a film between the back surface of the substrate 12 and the support pins 74, which is a countermeasure against sticking.

Hereinabove, the embodiments of the present disclosure have been described in detail, but the present disclosure is not limited to the above-described embodiments, and various modifications can be made without departing from the gist of the present disclosure.

For example, in the embodiments described above, the case has been exemplified in which, in the substrate processing performed by the substrate processing apparatus, a Si-containing gas is used as the source gas and an N-containing gas is used as the reactant gas, and the Si-containing gas and the N-containing gas are alternately supplied to form a SiN film on the substrate 12. However, the present disclosure is not limited thereto. That is, the processing gas used for the substrate processing is not limited to the Si-containing gas, the N-containing gas, and the like, and another type of gas may be used to form another type of thin film. Furthermore, even in a case where one type of processing gas is used or three or more types of processing gases are used as the film-forming gas, the present disclosure can be applied.

In addition, in the above-described embodiments, the case has been exemplified in which the film deposited on the front surface of the substrate 12 and the film deposited on the back surface of the substrate 12 are films having the same composition, but the present disclosure is not limited thereto. That is, the film deposited on the front surface of the substrate 12 and the film deposited on the back surface of the substrate 12 may be films having different compositions. For example, the film type of the film deposited on the front surface of the substrate 12 and the film type of the film deposited on the back surface of the substrate 12 may be different by using different gases for the first film-forming gas supplied to the front surface of the substrate 12 and the second film-forming gas supplied to the back surface of the substrate 12. For example, a silicon oxide (SiO) film may be formed on the front surface of the substrate 12, and for example, a SiN film may be formed on the back surface of the substrate 12. Also in the present embodiment, similar effects to those in the embodiment described above can be obtained.

In addition, in the above-described embodiments, the case has been exemplified in which the film deposited on the front surface of the substrate 12 and the film deposited on the back surface of the substrate 12 are films having the same thickness, but the present disclosure is not limited thereto. That is, the film deposited on the front surface of the substrate 12 and the film deposited on the back surface of the substrate 12 may be films having different thicknesses. For example, the second film-forming gas supplied to the back surface of the substrate 12 is diluted and supplied with an amount of an inert gas or the like larger than that of the first film-forming gas supplied to the front surface of the substrate 12. As a result, the film deposited on the front surface of the substrate 12 and the film deposited on the back surface of the substrate 12 may be films having different thicknesses. Also in the present embodiment, similar effects to those in the embodiment described above can be obtained.

In addition, in the embodiments described above, the case has been exemplified in which the gas supply mechanism that supplies a gas to the back surface of the substrate 12 is provided in the susceptor 64, but the present disclosure is not limited thereto. That is, a gas supply mechanism that can supply a gas to the back surface of the substrate 12 may be provided separately from the gas supply mechanism that can supply a gas to the front surface of the substrate 12.

The above-described embodiments and modified examples can be used in combination as appropriate. Processing procedures and processing conditions at this time can be similar to the processing procedures and processing conditions in the above embodiments and modified examples, for example.

According to the present disclosure, warpage of a substrate can be suppressed.

What is claimed is:

1. A substrate processing apparatus comprising:
a processing chamber that processes a substrate;
a first gas supply mechanism that supplies a first film-forming gas to a front surface of the substrate;
a second gas supply mechanism that supplies a second film-forming gas to a back surface of the substrate;
a substrate heating table that heats the substrate in the processing chamber;
a lifting/lowering mechanism that lifts and lowers the substrate at least between a first position where the substrate can be transferred into and out of the processing chamber and a second position which is closer to the substrate heating table than the first position and where the substrate is not in contact with the substrate heating table; and
a controller configured to be capable of controlling the first gas supply mechanism, the second gas supply mechanism, the substrate heating table, and the lifting/lowering mechanism so as to form films on both surfaces of the substrate while heating the substrate at the second position.

2. The substrate processing apparatus according to claim 1, wherein the second gas supply mechanism is provided in the substrate heating table.

3. The substrate processing apparatus according to claim 1, wherein
the lifting/lowering mechanism includes a substrate supporter that supports the substrate, and
the controller performs control to heat the substrate in a state where the substrate is supported on the substrate supporter at the second position.

4. The substrate processing apparatus according to claim 1, which is configured such that a supply condition of the first film-forming gas supplied from the first gas supply mechanism to the front surface of the substrate and a supply condition of the second film-forming gas supplied from the second gas supply mechanism to the back surface of the substrate can be each set.

5. The substrate processing apparatus according to claim 1, wherein a film deposited on the front surface of the substrate by the first film-forming gas supplied from the first gas supply mechanism and a film deposited on the back surface of the substrate by the second film-forming gas supplied from the second gas supply mechanism are films having the same composition.

6. The substrate processing apparatus according to claim 1, wherein a film deposited on the front surface of the substrate by the first film-forming gas supplied from the first gas supply mechanism and a film deposited on the back surface of the substrate by the second film-forming gas supplied from the second gas supply mechanism are films having different compositions.

7. The substrate processing apparatus according to claim 1, wherein a film deposited on the front surface of the substrate by the first film-forming gas supplied from the first gas supply mechanism and a film deposited on the back surface of the substrate by the second film-forming gas supplied from the second gas supply mechanism are films having the same thickness.

8. The substrate processing apparatus according to claim 1, wherein a film deposited on the front surface of the substrate by the first film-forming gas supplied from the first gas supply mechanism and a film deposited on the back surface of the substrate by the second film-forming gas supplied from the second gas supply mechanism are films having different thicknesses.

9. The substrate processing apparatus according to claim 1, wherein the controller is configured to be capable of performing control to place the substrate on the substrate heating table by the lifting/lowering mechanism every predetermined period during film formation on the substrate.

10. A method of manufacturing a semiconductor device, the method comprising:
transferring a substrate into and out of a processing chamber at a first position; and
lowering the substrate at least from the first position to a second position which is close to a substrate heating table that heats the substrate and where the substrate is not in contact with the substrate heating table, and supplying a second film-forming gas to a back surface of the substrate while supplying a first film forming gas to a front surface of the substrate while heating the substrate to form films on both surfaces of the substrate.

11. The method of manufacturing a semiconductor device according to claim 10, which is configured such that a supply condition of the first film-forming gas supplied to the front surface of the substrate and a supply condition of the second film-forming gas supplied to the back surface of the substrate can be each set.

12. The method of manufacturing a semiconductor device according to claim 10, wherein a film deposited on the front surface of the substrate and a film deposited on the back surface of the substrate are films having the same composition.

13. The method of manufacturing a semiconductor device according to claim 10, wherein a film deposited on the front surface of the substrate and a film deposited on the back surface of the substrate are films having different compositions.

14. The method of manufacturing a semiconductor device according to claim 10, wherein a film deposited on the front surface of the substrate and a film deposited on the back surface of the substrate are films having the same thickness.

15. The method of manufacturing a semiconductor device according to claim 10, wherein a film deposited on the front surface of the substrate and a film deposited on the back surface of the substrate are films having different thicknesses.

16. A non-transitory computer-readable recording medium recording a program that causes a substrate processing apparatus to execute, by a computer:
transferring a substrate into and out of a processing chamber at a first position; and
lowering the substrate at least from the first position to a second position which is close to a substrate heating table that heats the substrate and where the substrate is not in contact with the substrate heating table, and supplying a second film-forming gas to a back surface of the substrate while supplying a first film forming gas to a front surface of the substrate while heating the substrate to form films on both surfaces of the substrate.

17. The non-transitory computer-readable recording medium recording a program according to claim 16, which is configured such that a supply condition of the first film-forming gas supplied to the front surface of the substrate and a supply condition of the second film-forming gas supplied to the back surface of the substrate can be each set.
